(19) United States
(12) Patent Application Publication
(10) Pub. No.: US 2025/0022868 A1
(43) Pub. Date: Jan. 16, 2025

(54) STACK-TYPE SEMICONDUCTOR PACKAGE INCLUDING A PLURALITY OF SEMICONDUCTOR CHIPS STACKED ON A SUBSTRATE AND A METHOD OF MANUFACTURING THE SAME

(71) Applicant: SAMSUNG ELECTRONICS CO., LTD., SUWON-SI (KR)

(72) Inventor: YOUNG-DEUK KIM, Suwon-si (KR)

(21) Appl. No.: 18/739,580

(22) Filed: Jun. 11, 2024

(30) Foreign Application Priority Data
Jul. 13, 2023 (KR) 10-2023-0091068

(51) Int. Cl. H01L 25/18; H01L 23/00; H01L 23/31; H01L 23/48; H10B 80/00

(52) U.S. Cl. CPC H01L 25/18; H01L 23/3135; H01L 23/481; H01L 24/16; H01L 24/32; H01L 24/08; H01L 24/73; H01L 2224/08145; H01L 2224/08225; H01L 2224/16145; H01L 2224/16225; H01L 2224/32145; H01L 2224/32225; H01L 2224/73204; H01L 2225/06513; H01L 2225/06517; H01L 2225/06544; H10B 80/00

(57) ABSTRACT

A semiconductor package includes: a first base chip including a plurality of first vias; a chip stack disposed on the first base chip; and a second base chip disposed between the first base chip and the chip stack, wherein the second base chip includes a plurality of second vias, wherein the chip stack includes memory chips that are stacked on the second base chip, wherein each of the memory chips includes a plurality of third vias, and wherein the first base chip and the second base chip are logic chips.

### CROSS-REFERENCE TO RELATED APPLICATION

This U.S. non-provisional patent application claims priority under 35 U.S.C. § 119 to Korean Patent Application No. 10-2023-0091068, filed on Jul. 13, 2023, in the Korean Intellectual Property Office, the disclosure of which is incorporated by reference herein in its entirety.

### TECHNICAL FIELD

The present inventive concept relates to a semiconductor package and a method of manufacturing the same, and more particularly, to a stack-type semiconductor package including a plurality of semiconductor chips stacked on a substrate and a method of manufacturing the same.

### DISCUSSION OF THE RELATED ART

Small and multi-functional electronic devices have increased in demand as a result of ongoing development of an electronic industry. Thus, semiconductor devices used in the electronic devices have been under development to have small sizes and multi-functional characteristics. Accordingly, a semiconductor package including a plurality of semiconductor chips, which has through-electrodes and are stacked on each other in a vertical direction, has been under development.

### SUMMARY

According to embodiments of the present inventive concept, a semiconductor package includes: a first base chip including a plurality of first vias; a chip stack disposed on the first base chip; and a second base chip disposed between the first base chip and the chip stack, wherein the second base chip includes a plurality of second vias, wherein the chip stack includes memory chips that are stacked on the second base chip, wherein each of the memory chips includes a plurality of third vias, and wherein the first base chip and the second base chip are logic chips.

According to embodiments of the present inventive concept, a semiconductor package includes: a first base chip including a plurality of first vias; memory chips disposed on the first base chip; and a second base chip disposed between the first base chip and the memory chips, wherein the first base chip includes a memory controller, and wherein the second base chip includes a plurality of second vias and a physical layer interface.

According to embodiments of the present inventive concept, a semiconductor package includes: a substrate; an interposer substrate disposed on the substrate; a chip structure disposed on the interposer substrate; and a host disposed on the interposer substrate and spaced apart from the chip structure, wherein the chip structure includes: a first base chip including a plurality of first vias; a chip stack disposed on the first base chip; and a second base chip disposed between the first base chip and the chip stack and including a plurality of second vias, wherein the chip stack includes memory chips that are stacked on the second base chip, wherein each of the memory chips includes a plurality of third vias, wherein the first base chip includes a first circuit layer disposed in its lower portion, wherein the second base chip includes a second circuit layer disposed in its lower portion, and wherein the first circuit layer and the second circuit layer include different logic circuits from each other.

### BRIEF DESCRIPTION OF THE DRAWINGS

FIG. 1 is a plan view illustrating a semiconductor package according to embodiments of the present inventive concept.

FIG. 2 is a cross-sectional view taken along a line A-A′ of FIG. 1.

FIG. 3 is an enlarged view of a chip structure of FIG. 2.

FIG. 4 is a block diagram illustrating a memory system according to embodiments of the present inventive concept.

FIGS. 5A, 5B, 5C, 5D, 5E, 5F and 5G are cross-sectional views illustrating a method of manufacturing a semiconductor package according to embodiments of the present inventive concept.

### DETAILED DESCRIPTION OF THE EMBODIMENTS

Embodiments of the present inventive concept will now be described more fully with reference to the accompanying drawings, in which embodiments of the present inventive concept are shown.

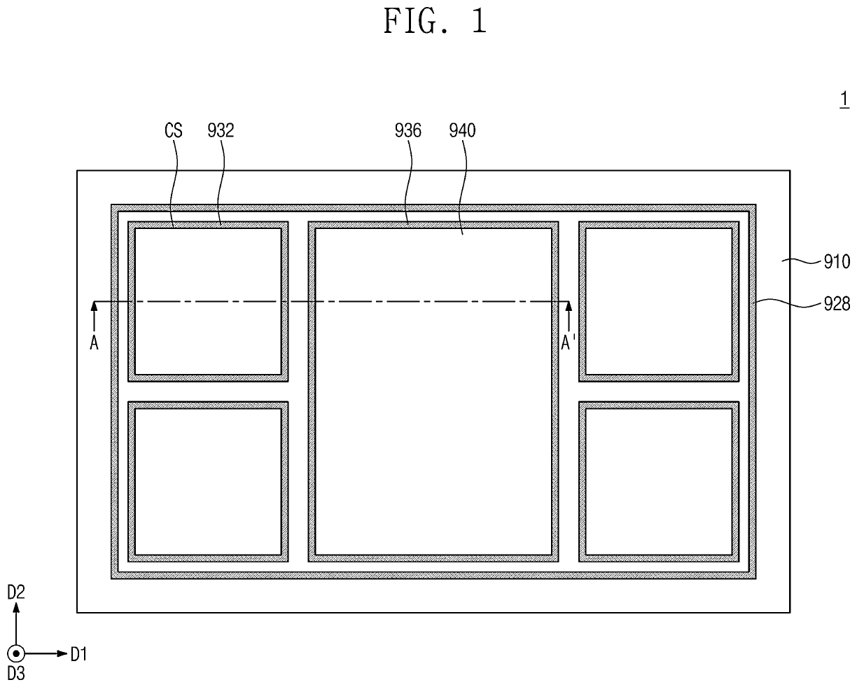

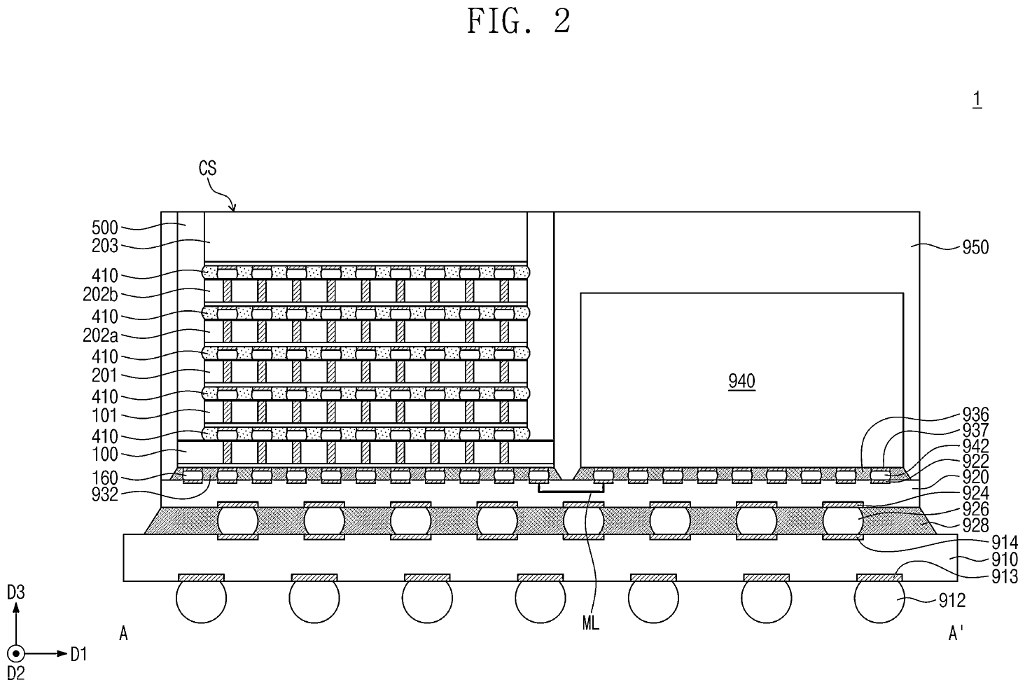

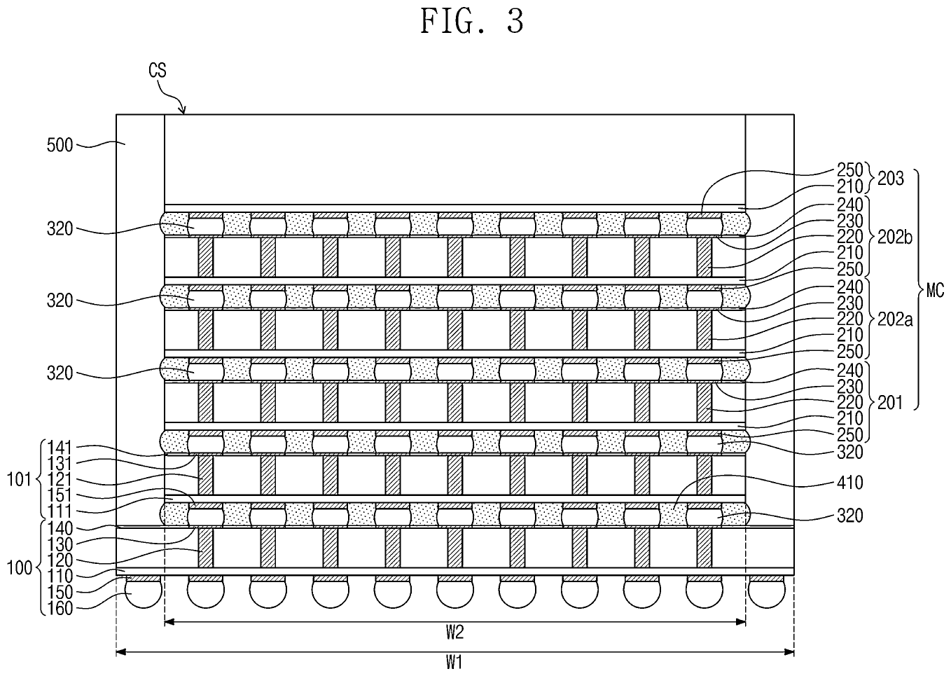

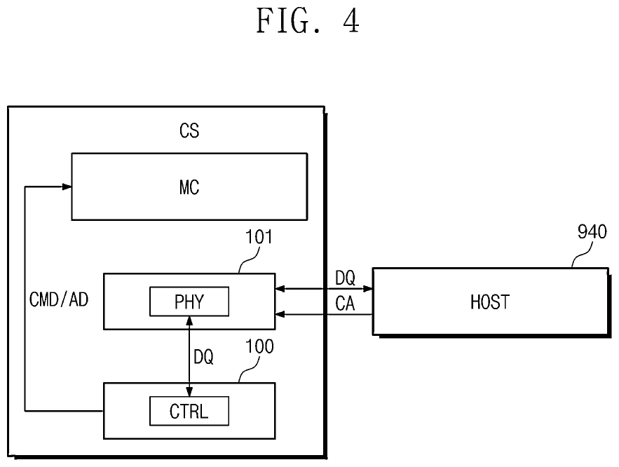

FIG. 1 is a plan view illustrating a semiconductor package according to embodiments of the present inventive concept. FIG. 2 is a cross-sectional view taken along a line A-A′ of FIG. 1. FIG. 3 is an enlarged view of a chip structure of FIG. 2. FIG. 4 is a block diagram illustrating a memory system according to embodiments of the present inventive concept.

Referring to FIGS. 1 to 4, a semiconductor package 1 according to embodiments of the present inventive concept may include a package substrate 910, an interposer substrate 920, a chip structure CS, and a host 940.

It is to be understood that a first direction D1 may be a direction parallel to a top surface of the package substrate 910. A second direction D2 may be a direction which is parallel to the top surface of the package substrate 910 and is perpendicular or substantially perpendicular to the first direction D1. A third direction D3 may be a direction perpendicular or substantially perpendicular to the top surface of the package substrate 910.

For example, the package substrate 910 may be a printed circuit board (PCB). The package substrate 910 may have a structure in which insulating layers and interconnection layers are alternately stacked on each other. The package substrate 910 may include a plurality of lower substrate pads 913 provided on its bottom surface, and a plurality of upper substrate pads 914 provided on its top surface.

First external connection terminals 912 may be disposed on the lower substrate pads 913, respectively. Each of the first external connection terminals 912 may include, for example, a solder ball or a solder bump. The first external connection terminals 912 may be provided in the form of a ball grid array (BGA), a fine ball-grid array (FBGA) or a land grid array (LGA), depending on a kind and arrangement of the first external connection terminals 912. For example, the first external connection terminal 912 may include an alloy including at least one of tin (Sn), silver (Ag), copper (Cu), nickel (Ni), bismuth (Bi), indium (In), antimony (Sb), or cerium (Ce).

The interposer substrate 920 may be provided on the package substrate 910. For example, the interposer substrate 920 may be a silicon interposer substrate. The interposer substrate 920 may include a lower interposer pad 924 provided on a bottom surface of the interposer substrate 920. The interposer substrate 920 may further include an upper interposer pad 922 provided on a top surface of the interposer substrate 920, and a metal line ML. The chip structure CS and the host 940, which will be described below in detail, may be electrically connected to the package substrate 910 through the interposer substrate 920.

First connection terminals 926 may be disposed between the package substrate 910 and the interposer substrate 920. For example, each of the first connection terminals 926 may be disposed between the upper substrate pad 914 and the lower interposer pad 924 and may be in contact with the upper substrate pad 914 and the lower interposer pad 924. The interposer substrate 920 may be electrically connected to the package substrate 910 through the first connection terminals 926. The first connection terminals 926 may include the same or similar metal material as the first external connection terminal 912.

A first underfill layer 928 may be provided between the package substrate 910 and the interposer substrate 920. The first underfill layer 928 may fill a space between the package substrate 910 and the interposer substrate 920 and may at least partially surround a side surface of each of the first connection terminals 926. For example, the first underfill layer 928 may include an epoxy resin.

The chip structure CS and the host 940 may be disposed on the interposer substrate 920. For example, the chip structures CS may be spaced apart from each other in the first direction D1 with the host 940 interposed therebetween. A plurality of the chip structures CS may be arranged in the second direction D2. The arrangement of the chip structure CS and the host 940 may be variously changed depending on a design of the semiconductor package 1.

The chip structure CS may include a first base chip 100, a second base chip 101, and a plurality of memory chips 201, 202a, 202b and 203.

The first base chip 100 and the second base chip 101 may constitute a chiplet structure. For example, the chiplet may be separate chips which have different functions (e.g., different functions of a logic chip) and are connected to each other by through-electrodes.

The first base chip 100 may include an integrated circuit therein. For example, the first base chip 100 may be a semiconductor chip including electronic elements such as transistors.

The first base chip 100 may include a first circuit layer 110, a first via 120, a first upper pad 130, a first protective layer 140, and a first lower pad 150. The first base chip 100 may have a first width W1 in the first direction D1.

The first circuit layer 110 may be provided in a lower portion of the first base chip 100. The first via 120 may vertically penetrate the first base chip 100. For example, the first via 120 may connect a top surface of the first base chip 100 to the first circuit layer 110. The first via 120 and the first circuit layer 110 may be electrically connected to each other. The first via 120 may be provided in plurality. As desired, an insulating layer at least partially surrounding the first via 120 may be provided. For example, the insulating layer may include at least one of silicon oxide (SiO), silicon nitride (SiN), silicon oxynitride (SiON), and/or a low-k dielectric layer.

An interconnection layer may be disposed on a bottom surface of the first circuit layer 110.

The first upper pad 130 may be disposed on the top surface of the first base chip 100. The first upper pad 130 may be connected to the first via 120. The first upper pad 130 may be provided in plurality. In this case, the first upper pads 130 may be connected to the first vias 120, respectively, and the arrangement of the first upper pads 130 may depend on the arrangement of the first vias 120. The first upper pad 130 may be connected to the first circuit layer 110 through the first via 120. The first upper pad 130 may include at least one of various metal materials such as copper (Cu), aluminum (Al), and nickel (Ni).

The first protective layer 140 may be disposed at the top surface of the first base chip 100 to at least partially surround the first upper pad 130. The first protective layer 140 may expose the first upper pad 130 and might not cover the upper surface of the first upper pad 130. The first base chip 100 may be protected by the first protective layer 140. The first protective layer 140 may be an insulating layer such as a silicon oxide layer or a silicon nitride layer.

The first lower pad 150 may be disposed on a bottom surface of the first base chip 100. For example, the first lower pad 150 may be disposed on a bottom surface of the first circuit layer 110. The first lower pad 150 may be electrically connected to the first circuit layer 110. The first lower pad 150 may be provided in plurality. The first lower pad 150 may include at least one of various metal materials such as copper (Cu), aluminum (Al), and nickel (Ni).

For example, the first base chip 100 may be a logic chip. The first base chip 100 may include a memory controller CTRL. In other words, the first base chip 100 may further include integrated circuits configured to control operations of memory chips MC. The first base chip 100 may be configured to provide command/address CMD/AD to a plurality of the memory chips MC through the memory controller CTRL. In other words, the first base chip 100 may be electrically connected to the plurality of memory chips MC. In addition, the memory controller CTRL may be configured to receive data signals from a physical layer interface PHY to be described below.

A plurality of second connection terminals 160 may be provided on the bottom surface of the first base chip 100. The second connection terminals 160 may be disposed on the first lower pads 150, respectively. The second connection terminals 160 may be electrically connected to the first circuit layer 110 and the first vias 120. In addition, in embodiments of the present inventive concept, the second connection terminals 160 may be disposed under the first vias 120. In this case, the first via 120 may penetrate the first circuit layer 110 so as to be exposed at the bottom surface of the first circuit layer 110, and the second connection terminal 160 may be directly connected to the first via 120. The second connection terminals 160 may include the same or similar metal material as that of the first external connection terminal 912.

The second base chip 101 may be disposed on the first base chip 100. The second base chip 101 may be spaced apart from the first base chip 100 in the third direction D3. The second base chip 101 may include a second circuit layer 111, a second via 121, a second upper pad 131, a second protective layer 141, and a second lower pad 151. The second base chip 101 may have a second width W2 in the first direction D1. The second width W2 may be less than the first width W1. The second width W2 may range from about 85% to about 95% of the first width W1.

The second circuit layer 111 may be provided on a bottom surface of the second base chip 101. The second via 121 may vertically penetrate the second base chip 101. For example, the second via 121 may connect a top surface of the second base chip 101 to the second circuit layer 111. The second via 121 and the second circuit layer 111 may be electrically connected to each other. The second via 121 may be provided in plurality. As desired, an insulating layer at least partially surrounding the second via 121 may be provided. For example, the insulating layer may include at least one of silicon oxide (SiO), silicon nitride (SiN), silicon oxynitride (SiON), or a low-k dielectric layer.

An interconnection layer may be disposed on a bottom surface of the second circuit layer 111.

The second upper pad 131 may be disposed on the top surface of the second base chip 101. The second upper pad 131 may be connected to the second via 121. The second upper pad 131 may be provided in plurality. In this case, the second upper pads 131 may be connected to the second vias 121, respectively, and the arrangement of the second upper pads 131 may depend on the arrangement of the second vias 121. The second upper pad 131 may be connected to the second circuit layer 111 through the second via 121. The second upper pad 131 may include at least one of various metal materials such as copper (Cu), aluminum (Al), and nickel (Ni).

The second protective layer 141 may be disposed at the top surface of the second base chip 101 to at least partially surround the second upper pad 131. The second protective layer 141 may expose the second upper pad 131 and might not cover the upper surface of the second upper pad 131. The second base chip 101 may be protected by the second protective layer 141. The second protective layer 141 may be an insulating layer such as a silicon oxide layer or a silicon nitride layer.

The second lower pad 151 may be disposed on the bottom surface of the second base chip 101. For example, the second lower pad 151 may be disposed on the bottom surface of the second circuit layer 111. The second lower pad 151 may be electrically connected to the second circuit layer 111. The second lower pad 151 may be provided in plurality. The second lower pad 151 may include at least one of various metal materials such as copper (Cu), aluminum (Al), and nickel (Ni).

For example, the second base chip 101 may be a logic chip. The second base chip 101 may include the physical layer interface PHY. The physical layer interface PHY may be a region in which an input/output circuit for an interface with the host 940 is formed. The physical layer interface PHY may be configured to provide command/address information to the memory controller CTRL, based on a command/address signal CA that is received from the host 940. The physical layer interface PHY may be configured to provide data information to the memory controller CTRL, based on a data signal DQ that is received from the host 940. In addition, the physical layer interface PHY may be configured to receive data information, based on a data signal DQ that is received from the memory controller CTRL. In other words, since the second base chip 101 includes the physical layer interface PHY, the second base chip 101 may be electrically connected to the host 940 and may include a logic circuit different from a logic circuit of the first base chip 100.

A chip stack may be disposed on the second base chip 101. The chip stack may include a plurality of the memory chips MC. Hereinafter, the chip stack and the plurality of memory chips MC will be described as the same component.

For example, the plurality of memory chips MC may include a first lower semiconductor chip 201, which is directly connected to the second base chip 101, first intermediate semiconductor chips 202a and 202b, which are disposed on the first lower semiconductor chip 201, and a first upper semiconductor chip 203, which are disposed on the first intermediate semiconductor chips 202a and 202b. The first lower semiconductor chip 201, the first intermediate semiconductor chips 202a and 202b, and the first upper semiconductor chip 203 may be sequentially stacked on the second base chip 101. The first intermediate semiconductor chips 202a and 202b may be stacked between the first lower semiconductor chip 201 and the first upper semiconductor chip 203. Two first intermediate semiconductor chips 202a and 202b may be disposed between the first lower semiconductor chip 201 and the first upper semiconductor chip 203 in the present embodiments, but embodiments of the present inventive concept are not limited thereto. In an embodiment of the present inventive concept, one first intermediate semiconductor chip or three or more first intermediate semiconductor chips may be disposed between the first lower semiconductor chip 201 and the first upper semiconductor chip 203, or the first intermediate semiconductor chips might not be provided between the first lower semiconductor chip 201 and the first upper semiconductor chip 203. The plurality of memory chips MC may have the second width W2 in the first direction D1. The plurality of memory chips MC may be the same kind of semiconductor chips having the same circuits as each other. The plurality of memory chips MC may be DRAM chips or NAND-FLASH chips.

The first lower semiconductor chip 201 may have a third circuit layer 210 facing the second base chip 101. For example, the third circuit layer 210 may include a memory circuit. In other words, a bottom surface of the first lower semiconductor chip 201 may be an active surface. The first lower semiconductor chip 201 may have a third protective layer 240 opposite to the third circuit layer 210. The third protective layer 240 may protect the first lower semiconductor chip 201. The third protective layer 240 may be an insulating layer such as a silicon oxide layer or a silicon nitride layer.

The first lower semiconductor chip 201 may have a third via 220 penetrating a portion of the first lower semiconductor chip 201 in a direction from the third protective layer 240 toward the third circuit layer 210. The third via 220 may be provided in plurality. An insulating layer may be provided to surround the third via 220. For example, the insulating layer may include at least one of silicon oxide (SiO), silicon nitride (SiN), silicon oxynitride (SiON), or a low-k dielectric layer. The third via 220 may be electrically connected to the third circuit layer 210.

A third upper pad 230 may be disposed in the third protective layer 240. A top surface of the third upper pad 230 may be exposed by the third protective layer 240 and might not be covered by the third protective layer 240. The third upper pad 230 may be connected to the third via 220. A third lower pad 250 may be disposed on the third circuit layer 210. For example, the third lower pad 250 may be disposed on a bottom surface of the third circuit layer 210. The third lower pad 250 may be connected to the third circuit layer 210. The third upper pad 230 and the third lower pad 250 may be electrically connected to each other, and the third circuit layer 210 and the third via 220 may be electrically connected to each other through the third upper pad 230 and the third lower pad 250. Each of the third upper pad 230 and the third lower pad 250 may be provided in plurality. Each of the third upper pad 230 and the third lower pad 250 may include at least one of various metal materials such as copper (Cu), aluminum (Al), and nickel (Ni).

The first intermediate semiconductor chips 202a and 202b may have substantially the same structure as the first lower semiconductor chip 201. For example, each of the first intermediate semiconductor chips 202a and 202b may include the third circuit layer 210, which faces the first base chip 100, the third protective layer 240, which is opposite to the third circuit layer 210, the third via 220, which penetrates each of the first intermediate semiconductor chips 202a and 202b in the direction from the third protective layer 240 toward the third circuit layer 210, the third upper pad 230, which is disposed in the third protective layer 240, and the third lower pad 250, which is disposed on the third circuit layer 210.

The first upper semiconductor chip 203 may have a substantially similar structure to that of the first lower semiconductor chip 201. For example, the first upper semiconductor chip 203 may include the third circuit layer 210, which faces the first base chip 100, and the third lower pad 250, which is disposed on the third circuit layer 210. The first upper semiconductor chip 203 might not have the third via 220, the third upper pad 230, and the third protective layer 240. However, embodiments of the present inventive concept are not limited thereto. In embodiments of the present inventive concept, the first upper semiconductor chip 203 may include at least one of the third via 220, the third upper pad 230, and/or the third protective layer 240. The first upper semiconductor chip 203 may have a thickness greater than those of the first lower semiconductor chip 201 and the first intermediate semiconductor chips 202a and 202b.

The first base chip 100, the second base chip 101 and the plurality of memory chips MC may be connected to each other through first chip terminals 320. The first chip terminals 320 may be solder balls formed of an alloy including at least one of, for example, tin (Sn), silver (Ag), copper (Cu), nickel (Ni), bismuth (Bi), indium (In), antimony (Sb), and/or cerium (Ce).

For example, some of the first chip terminals 320 may be disposed between the first upper pads 130 of the first base chip 100 and the second lower pads 151 of the second base chip 101. Others of the first chip terminals 320 may be disposed between the second upper pads 131 of the second base chip 101 and the third lower pads 250 of the first lower semiconductor chip 201. The others of the first chip terminals 320 may be disposed between the third upper pads 230 of the first lower semiconductor chip 201 and the third lower pads 250 of the first intermediate semiconductor chip 202a, between the third upper pads 230 of the first intermediate semiconductor chip 202a and the third lower pads 250 of the first intermediate semiconductor chip 202b, and between the third upper pads 230 of the first intermediate semiconductor chip 202b and the third lower pads 250 of the first upper semiconductor chip 203.

Some of the first chip terminals 320 may electrically connect the first base chip 100 to the second base chip 101. Others of the first chip terminals 320 may electrically connect the second base chip 101 to the first lower semiconductor chip 201. The others of the first chip terminals 320 may electrically connect the first lower semiconductor chip 201, the first intermediate semiconductor chips 202a and 202b and the first upper semiconductor chip 203 to each other.

Non-conductive layers 410 may be disposed between the first base chip 100 and the second base chip 101, between the second base chip 101 and the first lower semiconductor chip 201, between the first lower semiconductor chip 201 and the first intermediate semiconductor chip 202a, between the first intermediate semiconductor chips 202a and 202b and between the first intermediate semiconductor chip 202b and the first upper semiconductor chip 203, respectively. The non-conductive layers 410 may at least partially surround side surfaces of the first chip terminals 320. Each of the non-conductive layers 410 may include a non-conductive film (NCF) or non-conductive paste (NCP).

A first molding layer 500 may be disposed on the first base chip 100. The first molding layer 500 may cover side surfaces of the second base chip 101, the first lower semiconductor chip 201, the first intermediate semiconductor chips 202a and 202b and the first upper semiconductor chip 203. A level of a top surface of the first molding layer 500 may be substantially the same as a level of a top surface of the first upper semiconductor chip 203. For example, the top surface of the first molding layer 500 may be coplanar with the top surface of the first upper semiconductor chip 203. The first molding layer 500 may include an insulating material, and the insulating material may include a material such as an epoxy molding compound (EMC) or may include an adhesive material.

A second underfill layer 932 may be provided between the chip structure CS and the interposer substrate 920. The second underfill layer 932 may fill a space between the chip structure CS and the interposer substrate 920 and may at least partially surround a side surface of each of the second connection terminals 160. For example, the second underfill layer 932 may include an epoxy resin.

The host 940 may be disposed on the interposer substrate 920. The host 940 may be configured to generate various signals for controlling memory operations (e.g., write/read operations) and to transmit the generated various signals to the physical layer interface PHY included in the second base chip 101 of the chip structure CS. For example, the host 940 may be configured to generate the command/address signal CA, which includes various command information and address information (hereinafter, referred to as command/address information) for accessing data, and to generate the data signal DQ, which includes data information that is to be written, and configured to transmit the generated signals CA and DQ to the physical layer interface PHY. In addition, the host 940 may be configured to receive the data signal DQ including read data information.

The host 940 may include a graphic processing unit (GPU) die, a central processing unit (CPU) die, or a system-on-chip (SoC). For example, the host 940 may be a logic chip.

A host pad 937 may be disposed on a bottom surface of the host 940. Third connection terminals 942 may be disposed between the host 940 and the interposer substrate 920. For example, the third connection terminals 942 may be disposed between the host pads 937 and the upper interposer pads 922, respectively, and may be in contact with the pads 937 and 922. The host 940 may be electrically connected to the package substrate 910 through the third connection terminals 942. The third connection terminals 942 may include the same or similar metal material as that of the first external connection terminal 912.

A third underfill layer 936 may be provided between the host 940 and the interposer substrate 920. The third underfill layer 936 may fill a space between the host 940 and the interposer substrate 920 and may at least partially surround a side surface of each of the third connection terminals 942. For example, the third underfill layer 936 may include an epoxy resin.

A second molding layer 950 may be disposed on the interposer substrate 920. For example, the second molding layer 950 may cover a top surface of the interposer substrate 920. The second molding layer 950 may at least partially surround the chip structure CS and the host 940. A level of a top surface of the second molding layer 950 may be substantially the same as the level of the top surface of the chip structure CS. The second molding layer 950 may include an insulating material, and the insulating material may include a material such as an epoxy molding compound (EMC) or may include an adhesive material.

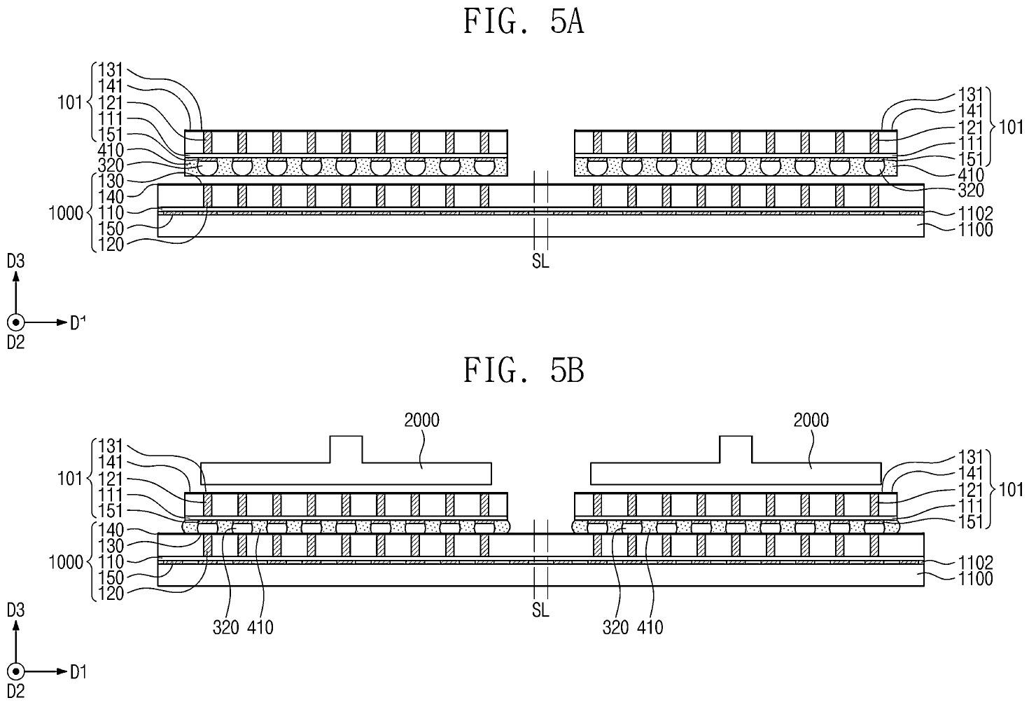

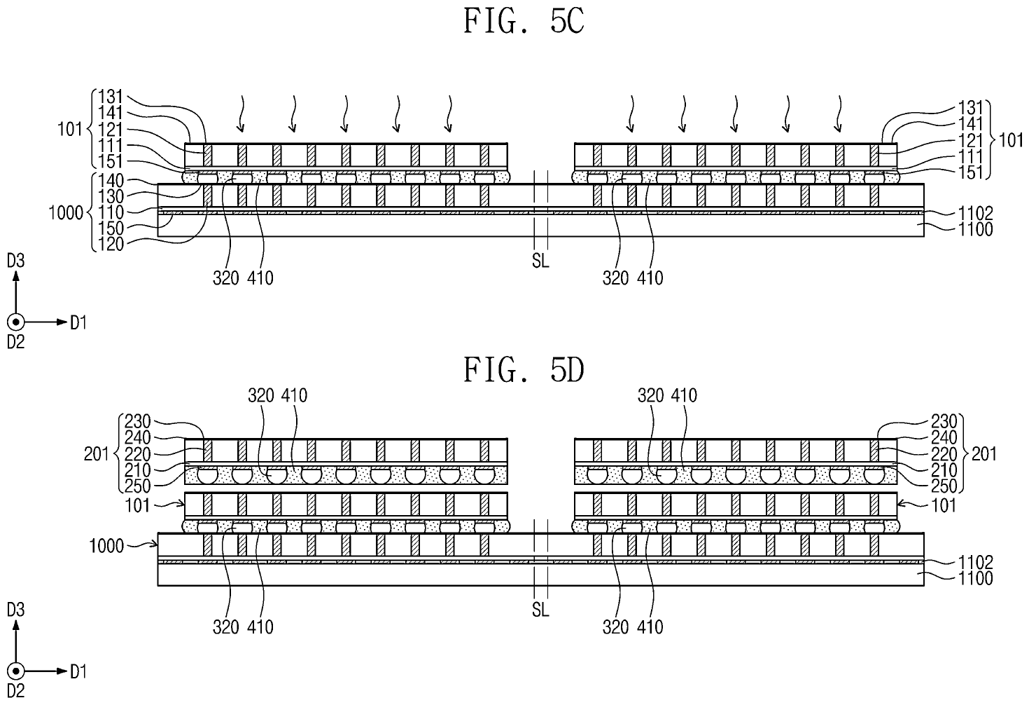

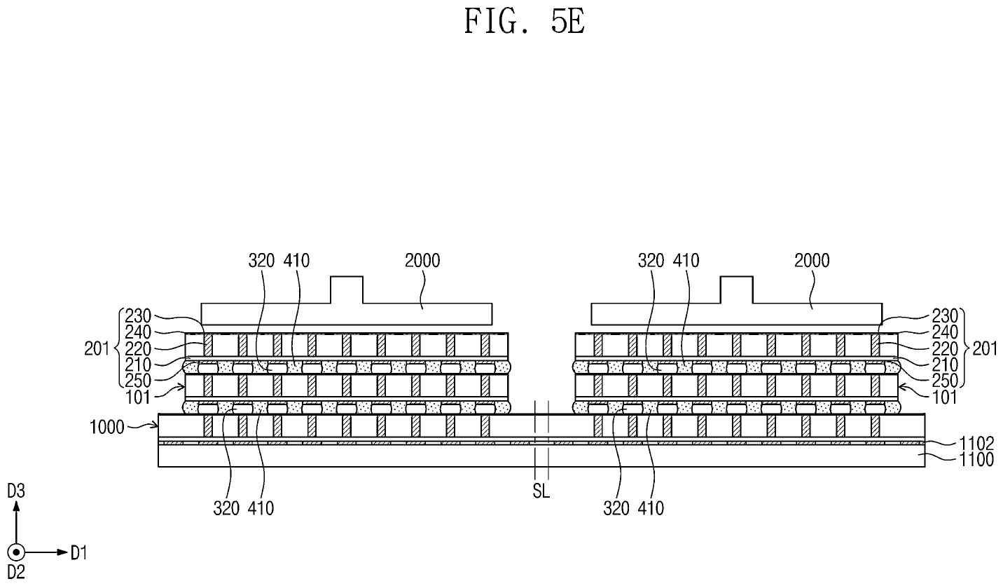

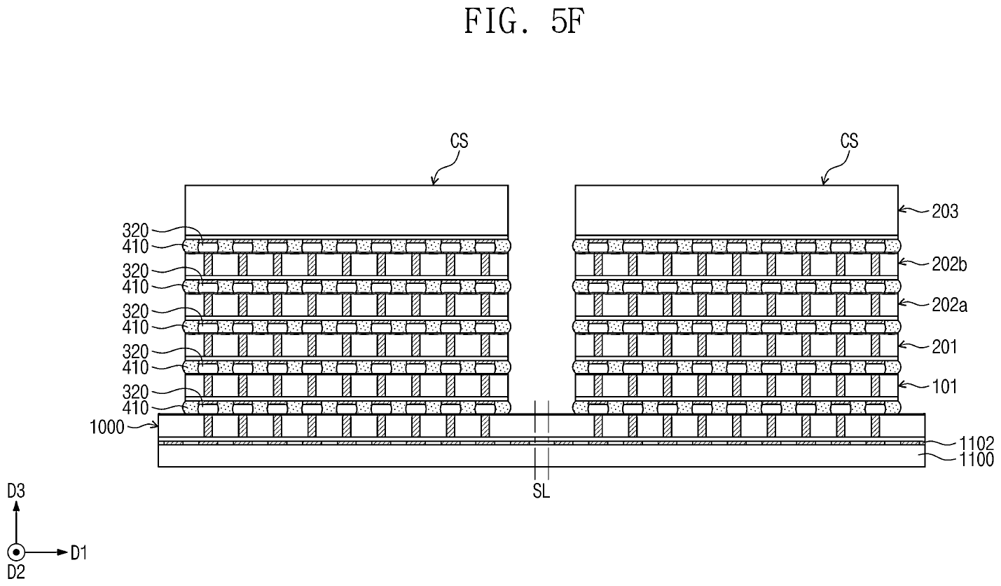

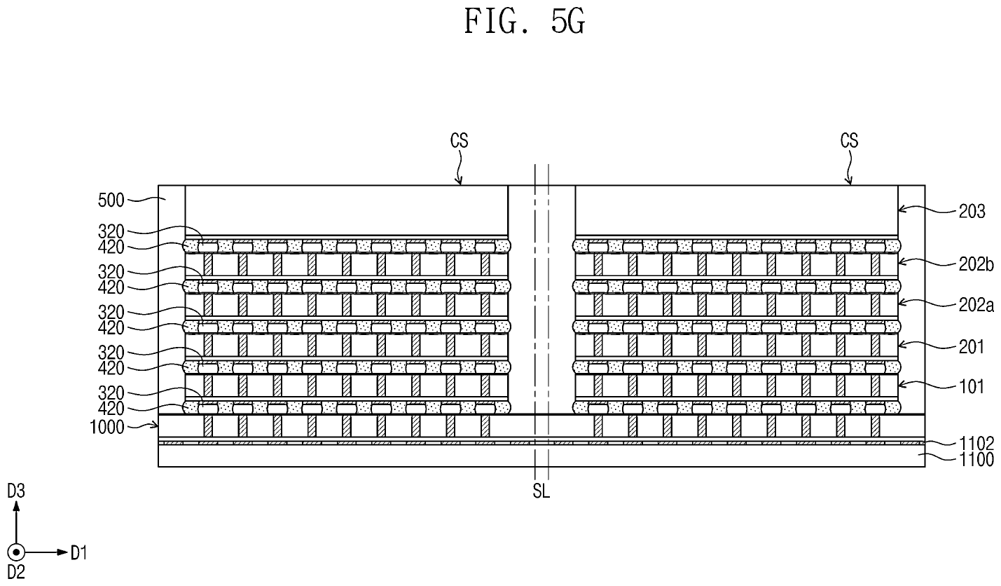

FIGS. 5A to 5G are cross-sectional views illustrating a method of manufacturing a semiconductor package according to embodiments of the present inventive.

Referring to FIG. 5A, a wafer 1000 may be provided. The wafer 1000 may have a top surface and a bottom surface, which are opposite to each other. For example, the wafer 1000 may include a silicon wafer or another semiconductor wafer. In embodiments of the present inventive concept, a printed circuit board (PCB), not the wafer, may be provided. The wafer 1000 may include a first circuit layer 110, a first protective layer 140 opposite to the first circuit layer 110, first vias 120, which penetrate a portion of the wafer 1000 in a direction from the first protective layer 140 toward the first circuit layer 110, first upper pads 130, which are disposed in the first protective layer 140, and first lower pads 150, which are disposed on the first circuit layer 110.

The wafer 1000 may be provided on a carrier substrate 1100. The carrier substrate 1100 may be an insulating substrate including, for example, glass or polymer or a conductive substrate including a metal. An adhesive member 1102 may be provided on a top surface of the carrier substrate 1100. For example, the adhesive member 1102 may include an adhesive tape. The wafer 1000 may be adhered to the carrier substrate 1100 in such a way that the first circuit layer 110 faces the carrier substrate 1100.

A plurality of second base chips 101 may be provided on the wafer 1000. Each of the second base chips 101 may include a second circuit layer 111, a second protective layer 141 opposite to the second circuit layer 111, a second via 121, which penetrates a portion of the second base chip 101 in a direction from the second protective layer 141 toward the second circuit layer 111, a second upper pad 131, which is disposed in the second protective layer 141, and a second lower pad 151, which is disposed on the second circuit layer 111. First chip terminals 320 and a non-conductive layer 410 at least partially surrounding the first chip terminals 320 may be provided on a bottom surface of each of the second base chips 101. For example, the non-conductive layer 410 may be a non-conductive film (NCF) or non-conductive paste (NCP). In the case in which the non-conductive layer 410 is the non-conductive paste, liquid non-conductive paste may be coated on the second base chip 101 by a dispensing process to form the non-conductive layer 410. In the case in which the non-conductive layer 410 is the non-conductive film, the non-conductive layer 410 may be formed by attaching the non-conductive film onto the second base chip 101. In embodiments of the present inventive concept, the non-conductive layers 410 may be provided on the wafer 1000, and then, the second base chips 101 may be provided on the non-conductive layers 410.

Referring to FIG. 5B, the second base chips 101 may be coupled onto the wafer 1000 by a thermal compression bonding process. For example, a width of a bonding tool 2000 that is used in the bonding process may be less than a width of the second base chip 101. When the second base chips 101 are compressed in a direction toward the wafer 1000, the non-conductive layers 410 may protrude beyond side surfaces of the second base chips 101.

Referring to FIG. 5C, a first thermal treatment process may be performed on the second base chips 101. The non-conductive layers 410 that are between the wafer 1000 and the second base chips 101 may be partially hardened by the first thermal treatment process.

Referring to FIG. 5D, first lower semiconductor chips 201 may be provided on the second base chips 101, respectively. Each of the first lower semiconductor chips 201 may include a third circuit layer 210, a third protective layer 240 opposite to the third circuit layer 210, a third via 220, which penetrates a portion of the first lower semiconductor chip 201 in a direction from the third protective layer 240 toward the third circuit layer 210, a third upper pad 230, which is disposed in the third protective layer 240, and a third lower pad 250, which is disposed on the third circuit layer 210. First chip terminals 320 and a non-conductive layer 410, which at least partially surrounds the first chip terminals 320, may be provided on a bottom surface of each of the first lower semiconductor chips 201.

Referring to FIG. 5E, the first lower semiconductor chips 201 may be coupled onto the second base chips 101, respectively, by a thermal compression bonding process. For example, a width of a bonding tool 2000 used in the bonding process may be less than a width of the first lower semiconductor chip 201; however, the present inventive concept is not limited thereto. Here, when the first lower semiconductor chip 201 is compressed in a direction toward the second base chip 101, the non-conductive layer 410 may protrude beyond side surfaces of the first lower semiconductor chip 201.

A second thermal treatment process may be performed on the first lower semiconductor chip 201. The non-conductive layer 410, which is disposed between the second base chip 101 and the first lower semiconductor chip 201, may be partially hardened by the second thermal treatment process.

Referring to FIG. 5F, the processes described in FIGS. 5A to 5E may be repeatedly performed to sequentially couple the second base chips 101, the first lower semiconductor chips 201, first intermediate semiconductor chips 202a and 202b and first upper semiconductor chips 203 onto the wafer 1000. The first lower semiconductor chip 201, the first intermediate semiconductor chips 202a and 202b and the first upper semiconductor chip 203, which are sequentially stacked on each other, may constitute a chip stack. First chip terminals 320 and non-conductive layers 410, which at least partially surrounds the first chip terminals 320, may be formed between the first lower semiconductor chips 201 and the first intermediate semiconductor chips 202a and between the first intermediate semiconductor chips 202a and the first intermediate semiconductor chips 202b.

Referring to FIG. 5G, a first molding layer 500 may be formed on the wafer 1000. For example, an insulating member may be applied onto the wafer 1000 to cover side surfaces of the second base chips 101, the first lower semiconductor chips 201, the first intermediate semiconductor chips 202a and 202b and the first upper semiconductor chips 203, and then, the insulating member may be hardened to form the first molding layer 500.

A singulation process may be performed on the first molding layer 500 and the wafer 1000 to separate chip structures CS and first molding layers 500 from each other. For example, a sawing process may be performed along a sawing line SL of the wafer 1000. The sawing process may be performed to cut the first molding layer 500 and the wafer 1000 that are between the chip structures CS.

An interposer substrate 920 may be mounted on a package substrate 910, and then, the chip structure CS and the first molding layer 500, which are formed by the sawing process, and a host 940 may be mounted on the interposer substrate 920. Thereafter, a second molding layer 950 may be formed to cover the first molding layer 500 and the host 940, thereby completing the semiconductor package 1.

In a chip structure according to a comparative example, a first base chip 100 may include a memory controller CTRL and a physical layer interface PHY. The memory controller CTRL and the physical layer interface PHY may generate heat when they are driven. However, the memory controller CTRL and the physical layer interface PHY may be disposed adjacent to each other in the first base chip 100 to deteriorate heat dissipation characteristics, and thus, quality of a semiconductor package may be reduced or deteriorated.

On the contrary, the chip structure CS of the semiconductor package 1 according to embodiments of the present inventive concept may include the first base chip 100 and the second base chip 101 that is disposed on the first base chip 100. The first base chip 100 and the second base chip 101 may include the memory controller CTRL and the physical layer interface PHY, respectively. In other words, in the chip structure CS of the semiconductor package 1 according to embodiments of the present inventive concept, the memory controller CTRL and the physical layer interface PHY may be separated from each other and may be disposed in separate base chips, respectively. For example, the physical layer interface PHY may generate more heat than the memory controller CTRL, and thus, the physical layer interface PHY that is in the chip structure CS according to embodiments of the present inventive concept may be included in the second base chip 101 and may be spaced apart from the memory controller CTRL in the first base chip 100.

As described above, the chip structure CS of the semiconductor package 1 according to embodiments of the present inventive concept may include the memory controller CTRL and the physical layer interface PHY which generate heat in operation and are respectively included in the separate base chips so as to be spaced apart from each other, and thus, the chip structure CS of the semiconductor package 1 may reduce a temperature by about 10% to about 15% as compared with the chip structure of the semiconductor package according to the comparative example. For example, a temperature of the base chip of the chip structure according to the comparative example may be about 103.5° C., but a temperature of the first base chip 100 and the second base chip 101 of the chip structure CS according to embodiments of the present inventive concept may be about 97.2° C. to reduce a temperature by about 9.8%. The heat dissipation efficiency of the semiconductor package 1 may be increased by the temperature reduction effect.

The semiconductor package according to embodiments of the present inventive concept may include the first base chip, the memory chip, and the second base chip between the first base chip and the memory chip. The first base chip may include the memory controller, and the second base chip may include the physical layer interface. The memory controller and the physical layer interface may be disposed in separate base chips, respectively, and thus, sources capable of generating heat may be separated from each other. As a result, the temperature in the semiconductor package may be reduced, and thus, the heat dissipation characteristics of the semiconductor package may be improved.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package comprising:
a first base chip comprising a plurality of first vias;
a chip stack disposed on the first base chip; and
a second base chip disposed between the first base chip and the chip stack, wherein the second base chip comprises a plurality of second vias,
wherein the chip stack comprises memory chips that are stacked on the second base chip,
wherein each of the memory chips comprises a plurality of third vias, and
wherein the first base chip and the second base chip are logic chips.

2. The semiconductor package of claim 1, wherein the first base chip and the second base chip comprise different logic circuits from each other.

3. The semiconductor package of claim 1, wherein the first base chip has a first width in a first direction that is parallel to a top surface of the first base chip,
wherein the second base chip has a second width in the first direction, and
wherein the second width is less than the first width.

4. The semiconductor package of claim 3, wherein the second width ranges from about 85% to about 95% of the first width.

5. The semiconductor package of claim 3, wherein each of the memory chips has the second width in the first direction.

6. The semiconductor package of claim 1, further comprising:
a molding layer disposed on the first base chip and covering the second base chip and the chip stack;
non-conductive layers disposed between the first base chip and the second base chip, between the second base chip and a lowermost memory chip of the memory chips, and between the memory chips that are adjacent to each other, respectively; and
chip terminals disposed in the non-conductive layer that is disposed between the first base chip and the second base chip, the non-conductive layer that is disposed between the second base chip and the lowermost memory chip, and the non-conductive layer that is between the memory chips that are adjacent to each other.

7. The semiconductor package of claim 1, wherein the first base chip and the second base chip are spaced apart from each other in a second direction perpendicular to a top surface of the first base chip.

8. A semiconductor package comprising:
a first base chip comprising a plurality of first vias;
memory chips disposed on the first base chip; and
a second base chip disposed between the first base chip and the memory chips,
wherein the first base chip comprises a memory controller, and
wherein the second base chip comprises a plurality of second vias and a physical layer interface.

9. The semiconductor package of claim 8, further comprising:
a substrate;
an interposer substrate disposed on the substrate; and
a host disposed on the interposer substrate,
wherein the first base chip is disposed on the interposer substrate and is spaced apart from the host in a first direction that is parallel to a top surface of the substrate, and
wherein the first base chip is configured to provide command/address to the memory chips through the memory controller.

10. The semiconductor package of claim 9, wherein the host is a logic chip, and
wherein the first base chip is configured to receive a data signal from the physical layer interface through the memory controller.

11. The semiconductor package of claim 9, wherein the second base chip is configured to provide command/address information to the memory controller, based on a command/address signal that is received from the host through the physical layer interface.

12. The semiconductor package of claim 9, wherein the second base chip is configured to provide data information to the memory controller, based on a data signal that is received from the host through the physical layer interface.

13. The semiconductor package of claim 9, wherein the host is configured to generate a command/address signal for accessing information and to transmit the generated command/address signal to the physical layer interface.

14. The semiconductor package of claim 9, wherein the host is configured to generate a data signal including information to be written and to transmit the generated data signal to the physical layer interface.

15. The semiconductor package of claim 9, wherein the first base chip and the second base chip are logic chips, and
wherein the host includes at least one of a graphic processing unit (GPU) die, a central processing unit (CPU) die, or a system-on-chip (SoC).

16. A semiconductor package comprising:
a substrate;
an interposer substrate disposed on the substrate;
a chip structure disposed on the interposer substrate; and
a host disposed on the interposer substrate and spaced apart from the chip structure,
wherein the chip structure comprises:
a first base chip comprising a plurality of first vias;
a chip stack disposed on the first base chip; and
a second base chip disposed between the first base chip and the chip stack and comprising a plurality of second vias,
wherein the chip stack comprises memory chips that are stacked on the second base chip,
wherein each of the memory chips comprises a plurality of third vias,
wherein the first base chip comprises a first circuit layer disposed in its lower portion,
wherein the second base chip comprises a second circuit layer disposed in its lower portion, and
wherein the first circuit layer and the second circuit layer comprise different logic circuits from each other.

17. The semiconductor package of claim 16, wherein the first base chip comprises a memory controller, and
wherein the second base chip comprises a physical layer interface.

18. The semiconductor package of claim 16, wherein the first base chip has a first width in a first direction that is parallel to a top surface of the substrate,
wherein the second base chip has a second width in the first direction, and
wherein the second width is less than the first width.

19. The semiconductor package of claim 16, wherein the first base chip and the second base chip are spaced apart from each other in a second direction that is perpendicular to a top surface of the first base chip.

20. The semiconductor package of claim 16, further comprising:
a first molding layer disposed on the first base chip and covering side surfaces of the second base chip and the memory chips; and
a second molding layer disposed on the interposer substrate and at least partially surrounding the chip structure and the host.
